(19) United States
(12) Patent Application Publication
(10) Pub. No.: US 2021/0319984 A1
(43) Pub. Date: Oct. 14, 2021

(54) METHOD AND APARATUS FOR LOW PARTICLE PLASMA ETCHING

(71) Applicant: EVATEC AG, Trübbach (CH)

(72) Inventors: Jürgen Weichart, Balzers (LI); Ben Curtis, Heiligkreuz (CH); Frantisek Balon, Buchs (CH)

(21) Appl. No.: 17/268,136

(22) PCT Filed: Aug. 13, 2019
(86) PCT No.: PCT/EP2019/071674

§ 371 Date: Feb. 12, 2021

(30) Foreign Application Priority Data
Aug. 15, 2018 (CH) 00992/18

(51) Int. Cl. H01J 37/32; H01L 21/3213

(52) U.S. Cl. CPC H01J 37/32522; H01J 37/32715; H01J 37/32568; H01J 37/32651; H01J 2237/20235; H01L 21/32136; H01J 2237/334; H01J 2237/2001; H01J 2237/2007; H01J 37/321

(57) ABSTRACT

A plasma etching device including a vacuum chamber for at least one plate shaped substrate with side walls looping around a central axis. The chamber including a substrate handling opening, at least one inlet for a reductive gas and an inert gas and a pedestal formed as a substrate support in a central lower area of an etching compartment of the chamber. The pedestal mounted in the chamber in an electrically isolated manner and connected to a first pole of a first voltage source, thereby forming a first electrode. The pedestal encompassing first heating and cooling means. A second electrode is electrically connected to ground and surrounds the first electrode. A third electrode is electrically connected to ground and includes at least one upper shield and a screen-shield both being thermally and electrically connected to each other, whereby the screen-shield loops around the etching compartment. At least one of the upper shield and the screen shield includes at least one further heating and/or cooling means. A vacuum pump system and an inductive coil loop around at least an upper sidewall defining the sidewall of the etching compartment. The one first end of the coil is connected to a first pole of a second voltage-source and one second end of the coil is connected to ground.

This invention relates to a plasma etching device according to claim 1 and a process to plasma-etch a semiconductor substrate in such a plasma etching device according to claim 20.

### Definitions & Measurement Equipment

AMOLED active matrix organic light emitting diode

CCDs charge-coupled device sensor

CH₄ methane gas

CTE coefficient of thermal expansion

ESC electrostatic chuck

ICP inductively coupled plasma

ITO oxide of indium and tin (InₓSn_{y}O_{z})

LCD liquid crystal display

LED light emitting diode

RIE reactive Ion etching

TCO transparent conductive oxide, e.g. ITO or zinc oxide (ZnO)

For Langmuir measurements to optimize systematically certain plasma parameters like ion and electron densities (Nₑ and Nᵢ, [cm⁻³]), floating and plasma potentials (V_{f} and Vₚ, [V]), electron temperature (Tₑ [eV]) and ion flux (Iᵢ [mA cm⁻²]) a Smart Probe™ automated modified Langmuir probe plasma diagnostic device from Scientific Systems has been used in a circular etching compartment of a CLN300E multi-chamber system, having a diameter of 480 mm and a height of 162 from the pedestal to the top. A modified flexible probe with a tip length of 6 mm and tip radius 0.7 mm has been moved through the grounded shields in the plasma in parallel to the pedestal/wafer surface in a distance of about 20 mm. For the test series a low pressure of about 0.1 Pa and a high pressure of about 0.5 Pa has been used. A MF-power of 1'000 W, at a frequency of 400 kHz has been applied by an MF-source to a 15 loops coil wound around the etching compartment. Such a basis configuration has been also used for further tests without Langmuir probe measurement using different gas mixtures and varying MF and RF-power. The measurement system has been triggered by an external trigger having a frequency >100 kHz wherewith a sawtooth signal from −50 to +50 V has been applied to the probe.

For particle measurement on a wafer surface after the etching process a Reflex Table Top laser surface analyzer from NanoPhotonics has been used. Thereby an ellipsoidal mirror is located so that its first focal point coincides with the laser spot on the wafer surface. It collects all light scattered from that point and focuses it in the second focal point, where a diaphragm is placed. The diaphragm allows only light coming from the laser spot to pass, thus reducing the effects of external illumination. Two flat mirrors are used to change the direction of light and thus make overall system smaller in size. Since such optical system is symmetrical relatively to the axis that is perpendicular to wafer surface, the amount of collected scattered light is independent of particle orientation relative to the optics. Such systems are capable in counting particles and characterize these in size as well as distinguish from scratches or haze effects on the wafer surface. They are used as standard system in the semiconductor metrology.

“Pasting” processes are processes using essentially the same setup as with production processes to sputter a material capable of gettering water vapor or volatile organic compounds from a substrate of the same dimensions as the product substrates. Basically the same process parameters can be used as for the product substrates, however in many cases slight modifications as a longer etch time and/or different sputter gases and/or pressure is applied. Pasting is seen as an alternative to either a time consuming shield change or a real back-etching of the films deposited on the walls, which is in many cases not possible or requires very aggressive plasma chemistry. Pasting is usually seen as a “reset” of the chamber to defined wall conditions, nevertheless after a certain period a shield change is usually required.

### TECHNICAL BACKGROUND AND SUMMARY OF THE INVENTION

Opto-electronic devices such as displays (LCDs, AMOLEDs, micro-LED), sensors (CCDs), amorphous silicon solar cells and the like often include thin-film transparent electrodes placed over a light transmitting or light emitting element. The transparent electrodes are typically composed of transparent conductive oxide (TCO). Typical examples of TCO are oxide of zinc (ZnO) and oxides of indium and tin (InₓSn_{y}O_{z}; e.g. 90% In₂O₃ and 10% SnO₂) commonly labeled as ITO. During the manufacturing the electrode material is deposited as a thin-film of TCO on a substrate. Thereafter the TCO is selectively etched to remove pre-selected portions and thereby define desired conductive paths or wiring. New developments, as for example in displays with very high definition and ultra-high resolution require to define the conductive TCO areas with very narrow line and space within sub-micron dimensions, whereto more effective micro/nanoscale processing is required. Thus, aspect ratios and critical dimensions of etched lines and islands together with a very tight particle specification are requested. Furthermore the TCO processes are towards the end of the entire process flow and such substrates or wafers are of considerable high value wherefore manufacturing yield plays an important role, so that front end particle specifications of at the maximum 0.04 particles >0.2 μm per cm² are applied to TCO processes, which refers to less than thirty particles (<30 pcs) of a size bigger than 0.2 μm in at least one dimension are allowed on a 300 mm wafer.

Such tight restrictions cannot be met easily with state of the art equipment for high volume production. To allow to meet such tight particle restriction more easily is one aim of the present invention which can be reached by an etching device and an etching process as disclosed in the following. This aim goes in line with the aim to provide an etching device of high flexibility with reference to the temperature management of different parts of the etching compartment. A further aim is to provide a device and a process whereby a wafer substrate can be heated fast to a high temperature of about 100° C. or more and hold at that temperature during the etching process without exceeding a maximum temperature critically for the substrate material. Which means in other words to hold and stabilize the substrate temperature under a high energy flux from the ICP-plasma and thermal load from the substrate bias. Another aim is to reduce essentially the number of service and pasting steps used to upheld high process specifications.

In an embodiment of the present invention the Plasma etching device comprises a vacuum chamber for at least one plate shaped substrate with side walls looping around a central axis A, the chamber including
a substrate handling opening, which can be a load-lock in case there is a big pressure difference between both sides of the opening;
at least one inlet for a reductive gas and an inert gas;
a pedestal formed as a substrate or workpiece support in a central lower area of an etching compartment of the chamber, the pedestal being connected to a first pole of a first source, which can be a RF-source, thereby forming a first electrode, the pedestal encompassing first heating and cooling means;
a second electrode, which is a counter electrode, and is RF-connected to ground and surrounding the first electrode; RF-connected hereby means a conductive connection adapted to ground safely parts exposed to an RF-plasma. Examples of such connections are explained in detail in WO2017/207144 and WO2017/215806 of the same assignee which will be shown later; the second electrode which comprises at least one lower shield to protect at least one of a chamber bottom, lower chamber parts, and a circumference of the pedestal and can be positioned towards the first electrode in dark room distance, which can be from 0.5 to 5 mm or from 0.8 to 2 mm with the typical process pressure range as applied with reactive ion etching (RIE) which is from 0.05 Pa to 0.7 Pa, or 0.1 Pa to 0.5 Pa.
a third electrode, which is also a counter electrode, is RF-connected to ground; the third electrode comprising at least one upper shield and a screen-shield both being thermally and electrically connected to each other, whereby the screen-shield loops around the etching compartment, which is in a vertical direction between the second electrode and the upper shield, the latter being mounted to a top wall of the vacuum chamber; these shields protect the inner surface of the chamber ceiling formed by the top wall and at least an upper part of chamber sidewalls from etching residuals, whereby screen shields are slotted in parallel or at least about parallel to central axis A;
thereby at least one of the upper shield and the screen shield comprises at least one further heating and/or cooling means configured to hold these shields permanently on a constant temperature level;
the device further comprises a vacuum pump system and an inductive coil looping around an upper sidewall, which defines the vacuum tight sidewall of the etching compartment and surrounds the screen shield, whereby one first end of the coil is connected to a first pole of a second voltage source, which can be a MF-source, and one second end of the coil is connected to ground to produce an inductively coupled plasma within the etching compartment of the vacuum chamber; whereby at least in the area between the top of the vacuum chamber or the upper shield and the pedestal, at least the upper wall of the vacuum chamber is made of ceramics, e.g. aluminum oxide or boron nitride, or is made of quartz.

It should be mentioned that in a basic version of the invention heating and cooling means and further or as mentioned below supplementary heating and/or cooling means can be supplied by a first heating and cooling device with respective heating or cooling fluid according to the process needs.

In a further embodiment the chamber may comprise temperature control means connected to the heating and cooling means to control heating and cooling of the pedestal and keep the substrate at a constant temperature between 30° and 200° C., e.g. between 60° and 180° C., see also table 1 below. The control means may comprise a control circuit to set heating power and/or cooling power in dependency of the substrate temperature measured by a temperature measurement device.

Additionally a lower shield which constitutes the surface of the second electrode can be connected to supplementary heating and/or cooling means or comprise supplementary heating and/or cooling means to keep the lower shield at a constant temperature, e.g. from −40° C. to 100° C. Similar to heating and cooling means or further heating and/or cooling means as mentioned above these supplementary heating and/or cooling means may be connected with temperature control means to hold the lower shield on constant temperature or adjust temperature to certain process needs (see also table 1 below).

Thereby at least one of the first heating means, further heating means, and supplementary heating means may comprise an electrical resistance heating device, a radiation heating device or at least one heating circuit comprising a heating fluid, and at least one of the first cooling means, further cooling means, and supplementary cooling means may comprise at least one cooling circuit encompassing a cooling fluid.

In addition, at least one of the first heating means, further heating means, and supplementary heating means may comprise a fluid circuit the intake of which is connected to two fluid reservoirs of different temperature and a mixing unit to set the heating/cooling temperature. The at least one heating and/or cooling circuit can be mounted within the chamber wall to heat or cool at least one of the shields by an extensive contact area between respective surfaces of the wall and shield.

The at least one gas inlet can be connected to the chamber or to the reservoirs of a reductive and an inert gas by usual pipes and gas lines and/or metering devices, e.g. mass-flowmeter control devices (MFCs), to meter the respective gas proportions. An additional inlet connected via additional gas lines ending in channels or cavities within the surface of the pedestal or the ESC directly below the wafer can be further connected to a cool gas reservoir which usually will be an inert gas too, e.g. Ar. Any valves as disclosed can be replaced by one or several MFCs when MFCs are provided with a secure gas stop function.

The reductive gas may comprise at least one of hydrogen, and a hydrocarbon gas volatile at room temperature and the inert gas may comprises at least one of Argon (Ar), Helium (He), Neon (Ne) and Xenon (Xenon). In one embodiment which has proofed to be very efficient in terms of low particle emission the reductive gas comprises hydrogen (H₂) and methane (CH₄) and the inert gas is Argon (Ar).

To avoid eddy current losses of ICP power within the screen, the screen shield can be slotted essentially in parallel to a central axis (A) of the pedestal, whereby slots can be tilted, e.g. from 25° to 45°, with reference to a radial direction originating from central axis A, to avoid a line of sight connection between the plasma and the sidewall and/or the bottom wall which also can be a part of the lower sidewall.

The upper shield and the screen-shield can be made as a single piece element, which can be formed pot-like and mounted upside down above the pedestal, whereby easy mounting and demounting for service is assured, e.g. via swiveling the pedestal and connected systems (depending on the actual construction: pedestal base, darkroom shield, first voltage source, lower sidewall, . . . ) by 180° or a service top cover which can be opened or lift of from the chamber.

In a further embodiment the thermal contact between the pedestal and the wafer may be improved by an electrostatic chuck (ESC), which can be foreseen in addition to mechanical clamping or alone if shadowing or stress by mechanical clamping should be avoided.

A further aim of the actual invention is to provide a process to plasma-etch a semiconductor substrate, e.g. a wafer, using a plasma etching device as disclosed above. Whereby as an example transparent conductive oxide (TCO) layers, having light transmitting or light emitting properties, like for instance indium tin oxide (ITO) or zinc oxide, can be etched from the substrate in the vacuum etching-chamber. Such layers may be masked partially by a photo resist to structure the surface of the substrate/wafer. Such a process comprises the following steps:
applying a vacuum to the chamber;
tempering the 2^{nd} electrode shields and the pedestal;
putting a substrate on the pedestal;
setting a process pressure by introducing a gas mixture comprising an inert gas and at least one reductive gas;
applying a power from the first voltage source to the pedestal to produce an etch bias;
applying a power from the second voltage source to the coil to produce an inductively coupled plasma (ICP);
etching the substrate surface by reactive ion etching (RIE), and
controlling the substrate temperature by adjusting the heating or cooling power of heating and cooling means coupled to the pedestal in dependency of the substrate temperature measured by a temperature measurement device.

The reductive gas may comprise or consist of at least one of a hydrocarbon being volatile at room temperature, which can be methane, and hydrogen. Other hydrocarbons could be other volatile alkanes, like ethane, propane, cyclopropane, butane, however small molecules with single carbon-bonds are preferred to avoid plasma polymerization. When methane is used a proportion from 10 to 50% can be adjusted in the gas mixture. Hydrogen can be used alone or together with a hydrocarbon, e.g. methane, in a proportion from 5 to 30% in the gas mixture. In one embodiment which has proofed to be very efficient in terms of low particle emission the reductive gas comprises hydrogen (H₂) and methane (CH₄) and the inert gas is Argon (Ar).

A substrate surface to be etched can be heated to or near an etch temperature between 30° and 200° C. by at least one of heating the pedestal with heating and cooling means and heating a substrate surface by radiation heating. Thereby controlling of the substrate temperature especially when in the following etching of the surface takes place plays an important role. Therefor a control circuit may be used during the process to keep the etch temperature constant within ±10° C. by at least controlling the temperature of the pedestal in a temperature region from −40 to 200° C. in dependency of at least one of a pedestal or shield reference temperature measured with an electric temperature measurement device (37′) and/or a substrate reference temperature measured with an optic measurement device (37) at the back-side surface of the substrate. This control value or values can be used to control the first heating/cooling device, e.g. via a central control panel, to regulate flow and temperature of a heating/cooling fluid or the power of a radiation heater as examples. It should be mentioned that this may comprise a considerable change in the heat to be fed to or taken from the pedestal. E.g. at the beginning of a process heat has to be transferred from the pedestal to the substrate, which may be an ITO coated and photo resist masked wafer. After having reached a process temperature of 100 to 120° C. the etching process starts whereby depending on the etch energy used, the surface temperature as well as the temperature of the substrate itself could quickly rise, without controlled change of temperature flow from the heating and cooling means. Whereby, as an example, a cold fluid could be admixed to the heating fluid or even could replace that fluid completely at the beginning or during any point of time during the etching process, where mixing can be performed stepwise or in a continuous way.

A temperature measurement device as used to control the temperature of the pedestal or one of the (electrode) shields may comprise at least one of a thermocouple, thermistor, resistance temperature detector (RTD) in a surface, e.g. of the pedestal or a shield, or a remote, e.g. optic measurement device for a substrate surface, a pedestal surface or a shield surface exposed to etching. Whereby primarily such control circuits and measurement devices will be foreseen with the pedestal or a pedestal surface in close vicinity to the substrate which can be combined with a remote back-side surface measurement of the substrate itself to enable an even tighter temperature control as a function of two temperatures or temperature profiles. As remote measurement devices optical devices like infrared measurement devices or a pyrometer can be used.

To improve thermal contact between wafer and pedestal an electrostatic chuck (ESC) can be used.

Tempering may comprise also the heating of the third electrode shield(s), which are the upper shield and the screen shield, to a temperature between 30° and 100° C., to avoid largely the formation of layers from etching residuals, e.g. from etched ITO surfaces, by reacting such residuals on the surface to volatile compounds. For that purpose the partial pressure of the at least one reductive gas, e.g. methane (CH₄) or hydrogen and methane, can be set to avoid mostly deposition of oxidized species at least on the surface of the upper shield and screen-shield. Especially when using relatively thick shields of 3 to 6 mm thickness, the further heating and/or cooling means need not be to be coupled directly to all shields of the third electrode but may be confined to a tight thermal contact between the top wall and the upper shield whereby adequate heat flow can be provided from the upper shield to the screen shield for tempering, e.g. during loading, preheating or a service step, and vice versa if cooling is necessary during the etching process.

Tempering may also comprise heating or cooling of the lower shield(s) to a temperature between −40° (minus forty) and 100° C. This may vary up to the specific process needs and simplicity of process by either keep the lower shield cooler than other surfaces in the chamber to trap particles which could not be reacted to volatile compounds and be pumped away, or keeping the lower shield of the second electrode at the same temperature like the other shields, which would allow to use the same further heating and cooling device for the shields of the 2^{nd} electrode (lower shield) and the 3^{rd} electrode (screen shield and upper shield).

As a rule of thumb, temperature ranges which should be able to be applied to different parts of the vacuum chamber to meet the needs of different etching processes as discussed above can be found in table 1 below. The highest flexibility can be met with a chamber where temperature ranges as given in column ΔT flex can be applied to substrate(s), pedestal and different shields in the chamber, whereas column ΔT opt gives the temperature range where best results for usual RIE processes on TCO or ITO coated wafers, e.g. silicon wafers, could be achieved in terms of fast etching rate and low particle emission. Whereas ΔT med gives a good mixture of high process flexibility and good results.

TABLE 1

| | ΔT flex | ΔT med | ΔT opt |
|---|---|---|---|
| Substrate | 30-200° C. | 60-120* (180) ° C. | 80-150° C. |
| Pedestal | −40-200° C. | −40-120° C. | 0-100° C. |
| Upper shield & | 30-150° C. | 60-100° C. | 70-90° C. |
| screen shield | | | |
| Lower-shield | −40-150° C. | 30-100° C. or | 40-70° C. |
| | | −40-10° C. if used | |
| | | as a cold trap? | |

*This temperature range would apply to photo resist layer coated substrates, whereas the higher temperature range would be best to etch Wafer blanks.

Thereby the first voltage-source is an RF-source and can be driven with a frequency from 2 MHz to 30 MHz, or from 3 to 27.01 MHz, or at 13.56 MHz. Thereby a power in the range from 0.3 Wcm⁻² to 1.4 Wcm⁻², or from 0.6 Wcm⁻² to 0.8 Wcm⁻² should be applied.

The second voltage-source, which is the ICP-source is an MF-source and can be driven with a frequency from 300 to 2'100 Hz, or from 350 to 600 Hz. Thereby a power of 600 to 1200 W should be applied to the coil by the second source giving an electron density from 1 e¹⁰ cm⁻³ to 5 e¹¹ cm⁻³ or from 3 e¹⁰ cm⁻³ to 3 e¹¹ cm⁻³.

By applying such inventive processes to an ITO coated wafer, an ITO-etch rate of 0.6 to 1.2 nm/s can be achieved.

Further on a series of inventive processes as described above is disclosed which are characterized by a pasting parameter

P{f_{PR_cov}}=(No of produced wafers)/(No of pasting wafers),

for, e.g. single or multiple wafer processes where PR_cov is the surface coverage of the TCO layer, e.g. an ITO layer, with photo resist, and P{f_{PR_cov}} can be chosen at least within one of the following ranges from P(PR_Cov) at least to P(PR_Cov) opt as shown in table 2 below, whereby PR_Cov refers to different surface coverages of a TCO-coated wafer:

TABLE 2

| | P(PR_Cov) | P(PR_Cov) |
|---|---|---|
| PR_Cov | at least | opt |
| 80% | 25 | 50 |
| 50% | 100 | 200 |
| 0% | 2′000 | 10′000 or 250 μ |
| | | ITO removed |

Thereby an in film adders count could be measured consistently below 30, for particles >0.2 μm, for every single process, which means that there are less than 30 submicron defects on the whole surface of a 300 mm wafer. This again shows the high potential of the present inventive process as state of the art processes often need a pasting parameter between P {f_{PR_cov}} 1 and 10 to keep process dust in adequate levels.

Further on a series of inventive processes as described above is disclosed which are characterized in that shield temperature(s) of at least the screen shield and the upper shield is(are) constantly held at elevated temperatures before, during and after the first process of a series and in between the single processes of the series, e.g. in accordance to the necessities of the pasting processes strongly depending on the photoresist coverage as mentioned above from 25 to 50, from 100 to 200 or 2'000 to 10'000 RIE processes, until the shield(s) are changed for service. Thereby essentially constant heat conditioning before processing as well as in idle times is applied.

### EXAMPLES AND FURTHER EMBODIMENTS

The invention shall now be further described with the help of schematically and simplified figures and examples. With figures as described in the following same reference numbers refer to same features or at least features having the same function:

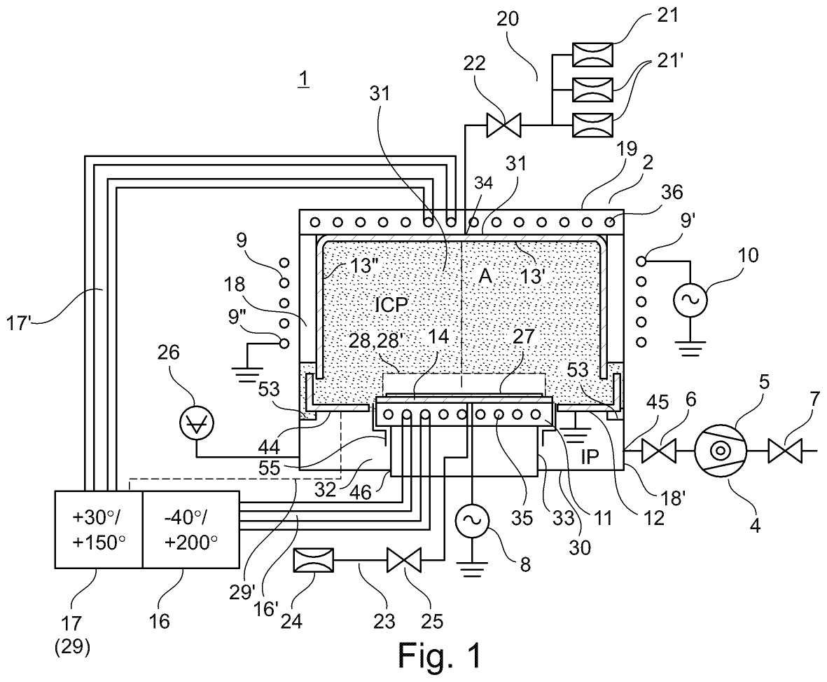

FIG. 1: An embodiment of an ICP-etch apparatus according to the invention;

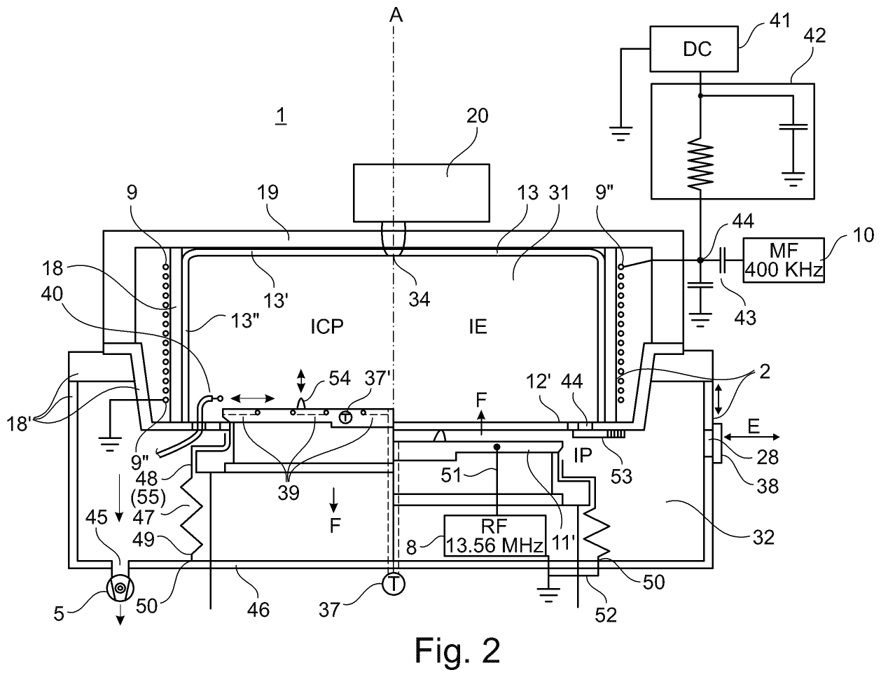

FIG. 2: A further embodiment of an inventive ICP-etch apparatus;

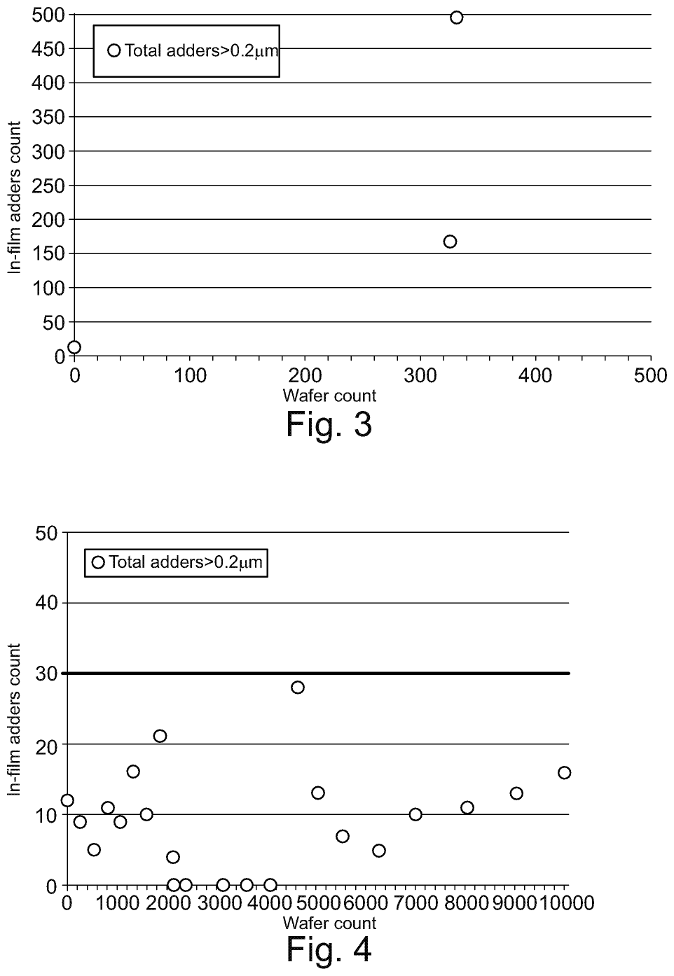

FIG. 3: Particle performance of state of the art etching processes;

FIG. 4: Particle performance inventive etching processes.

Etching of wafer blanks as well as etching TCO-coated, e.g. ITO-coated wafers has been performed on a Clusterline CLN300E multi-chamber system from Evatec AG equipped with an lop Etch Module 1 modified according to the present invention, which is merely schematically shown in FIG. 1. In an etching compartment 31, confined by electrode shields (12, 13, 13′, 13″) of a second electrode 12 and a third electrode 13, a wafer 27 is placed on a pedestal 11 which constitutes a first electrode being connected to a usually 13.56 MHz RF-source 8 and confines the etching compartment 31 in a lower central area. The pedestal is equipped with an ESC 14 for better thermal coupling of the wafer 27. The pedestal 11 further has an internal liquid circuit 35 which is connected to a first heating/cooling system 16 via 1^{st} heating/cooling lines 16′ to temper or cool the substrate. A window of an IR-temperature measurement system 37′ is positioned in line of sight by an optical path, see dotted lines between thermocouple 37′ and back-side of the substrate 27, or by a glass fiber optic to a central area of the backside of the wafer to enable regulation of the flow and temperature of the cooling fluid in dependency of the back-side surface temperature. This temperature measurement is used in combination with a thermocouple measurement system 37′ connected to the pedestal (or if used to the ESC) which gives a better process control than one stand alone system.

Second and third electrode 12, 13 are counter electrodes which both are connected to ground potential. The shields 12 of the second electrode are looped around the pedestal 12 in observance of a dark room distance to separate the etching compartment 31 from the pumping compartment 32 and have at least one respective opening, like a slit or a grid covered opening, to enable a high pumping conductance towards the vacuum pump system 4 comprising pump valve 6, high vacuum pump 5 and exhaust valve 7, the latter leading to a backing pump (not shown). A dark space shield 55 protects the circumference of the pedestal and its cylindrical base; at least where the base is too on RF-potential.

Upper shield 13′ and screen shield 13″ from the third electrode 13 are pot like and made from one piece for optimal thermal conductance, with a central gas inlet 34 connected to a first gas supply 20, comprising a first gas inlet valve 22, and first gas reservoir comprising a sub reservoir 21 for Argon or another inert gas and two sub reservoirs 21′ for reducing gas, here methane and hydrogen. The shield 13′ is mounted in tight thermal contact to the top-wall 19 which comprises a further internal liquid circuit 36 connected to a further (2^{nd}) heating/cooling device via further (2^{nd}) heating/cooling lines. Additionally shields 12 of the second electrode could be cooled by supplementary (2^{nd}) heating/cooling lines 29′—shown in dashed lines—which can be connected to the further heating/cooling device 17 or to a separate heating/cooling device 29.

The vacuum chamber 2 is confined by a bottom wall 30, the top wall 19 and sidewalls 18, 18′ and houses the etching 31 and the pumping compartment 32. The bottom wall 30 comprises the feed through 46 for the basis 33 of the pedestal wherein also respective electrical, cooling liquid and gas feed throughs for the pedestal 11 are foreseen. The top wall 19, comprises connections for the as mentioned further internal liquid circuit 36 and a feed through for the central gas inlet 34. Bottom wall 30 and lower sidewall 18′ can form a metal surrounding wall and together with the lower shield 12 and the outer circumference of the basis 33, form the pumping compartment 32. Sidewalls with the present embodiment, that is with the pumping compartment below the etching compartment 31, comprise a lower sidewall 18′ round the pumping compartment, which is made from a usual stainless steel material or aluminium for vacuum equipment, and the upper side wall 18, looping around the central axis A and the etching compartment 31, which is made of aluminum oxide ceramics to enable inductive coupling from coil 9 to the etching compartment 31 where the inductively coupled plasma (ICP) is ignited. A coil 9 is looped around the upper sidewall and is connected with its first end 9′ to MF-supply 10, and with its second end 9″ to ground. A vacuum gauge 26 is attached to the lower sidewall 18′ to control pumping speed in dependency of the process parameters set.

Wafers 27 can be fed and discharged through a substrate handling opening 28—shown in dashed lines—to the “static” pedestal 11, which means that the pedestal is not moved in a vertical direction before a loading or discharging operation takes place. For loading and unloading movable (see vertical double arrow) pins 54 are used to receive the substrate 27 and to allow the fingers from the handler to lift the substrate from the pedestal. During the process pins 54 stay retracted in the pedestals 11, 11′ surface (not shown). As an additional feature a back gas supply 23, comprising a back gas reservoir 24, e.g. with Ar or Ne, and a back gas inlet valve 25 can be foreseen with at least one feedthrough to a channel-structure 39 having a high flow resistance in the surface of the pedestal 11 or the ESC, as far an ESC is used instead of mechanical clamping, to better heat or cool the substrate 27 under vacuum conditions. The channel-structure 39 may be e.g. cobweb or labyrinth like and thereby lead from a central feedthrough, or especially for wafers having diameters of 25 mm or more, be lead from several feedthroughs to the outer circumference and all areas of the pedestal or ESC 14. Due to the contact pressure produced by mechanical clamps or the ESC 14, with reference to the process pressure, a higher back gas pressure can be applied to the uncoated reverse side of the wafer 27 without disturbing leakage to the etching compartment 31.

With reference to a plasma treatment device 1 having a static chuck, e.g. a plasma etching device for at least one plate shaped substrate, such an embodiment of an inventive device may comprise the following features:
A vacuum chamber 2 with a side wall 18, 18′ looping around a central axis A and comprising a pumping port;
A screen 13″ within said vacuum chamber looping around said central axis A and along a part of said side wall 18;
A stationary substrate support 11, which is a pedestal, exposed to the inside of said screen 13″ and adapted to support a plate shaped substrate 27 at one of its two-dimensionally extended surfaces and along a support-plane E perpendicular to said central axis A and
At least one substrate-handling opening 28 in said side wall 18 with an opening central axis perpendicular to and intersecting said central axis A;
At least one substrate handling cut-out 28′ in said screen 13″, said substrate handling opening 28 and said substrate handling cut-out 28′ being mutually aligned and tailored to allow handling of a plate shaped substrate towards and from said substrate support 11 there through;
A drivingly movable screen-shutter (not shown) drivingly freeing and covering said substrate-handling cut-out 28′; said screen having an electrically conductive surface, said screen-shutter having an electrically conductive shutter-surface, being in electric contact with said electrically conductive surface of said screen at least when said cut-out is covered by said screen-shutter; said stationary substrate support 11 comprising an electrically conductive support surface for the plate shaped substrate, electrically connected to an RF biasing source connector of said chamber; wherein said screen 13″ is electrically connected to a system ground connector 52 of said chamber 2, via said side-wall; and further comprising a lower shield forming a second electrode 12 and looping around said central axis A and complementing said screen, said lower shield being of metal, said screen 13″ being, at its lower rim, in electric contact with said lower shield as well as with said side wall 18′, said lower shield being otherwise electrically isolated from the other parts of said vacuum chamber with the additional exception of being firmly electrically connected to said system ground connector.

With reference to further embodiments and examples of a plasma etching device comprising a static chuck operated with lift pins, it is referred to WO 2017/215806 which is hereby integrated by reference in its entirety.

A further embodiment of an ICP-etch apparatus 1 is shown in FIG. 2 which comprises a “dynamic” chuck 11′ which can be lowered—vertical arrow in downwards direction—from a process position for wafer etching as shown on the left side into a loading position as shown on the right side of the split representation and vice versa—vertical arrow in upwards direction. Thereby substrate handling opening 28 and gate 38, here a load lock which can be moved in an upwards/downwards direction—vertical double arrow—can be positioned below the bottom/lower level of the etching compartment 31 without the need to disturb the symmetry of the etching compartment by a gate 28 which has to pass both the upper wall 18 and the screen shield 13″ as with the embodiment shown in FIG. 1. As with FIG. 1 substrates/wafers can be moved in a horizontal plane—horizontal double arrow—into and out of the chamber, e.g. by a handling system placed in a central chamber of a multi-chamber system like CLN300E (not shown).

Further on FIG. 2 shows a variation of the power supply for coil 9 to influence the density of the plasma by combining MF-source 10 with a direct current (DC) source 41, which can be a modulated DC-source, e.g. a pulsed DC-source. In use, a direct current is fed to the induction coil 9 together with the MF-signal via an adapter network 43 comprising two capacities, one between junction 44 and MF-source, the second between junction 44 and earth. The adapter network 43 serves to adapt the original resistance of the MF-source 10 and the impedance induction coil 9 and the etching compartment 31 and/or the ICP produced therein, thus making it possible to obtain a highly effective coupling of the middle-frequency power together with a uniform ion etch distribution on the area of the pedestal. The DC-source can be connected to the junction 44 via a low-pass filter 42 which may comprise, for example, a coil and a capacitor connected in parallel. Preferably the direct current can reach the induction coil 2 while the high-frequency current is blocked, so that the latter cannot find its way into the direct current source 41.

Langmuir probe 40 as used for plasma-diagnostic measurements can be seen to be placed slightly above the pedestal 11 and the wafer, whereby the probe tip could be positioned flexible from a peripheral zone outward a projected circumference of the pedestal 11 up to the center of the plasma round axis A as displayed by horizontal double arrow. Of course, such measurements have been made only with test cycles to avoid any pollution of a wafer surface during production due to dust formed on the surface of the measurement equipment.

With reference to a plasma etching device 1 having a dynamic, which is a movable, pedestal, such a device may comprise a vacuum chamber 2 and within said vacuum chamber:
an etching compartment 31 with a central axis A and comprising a surrounding wall 18 enclosing an inner space IE of said etching compartment 31 and comprising the etching equipment, e.g. pedestal 11′, of the etching device;
a pumping compartment 32 with a metal surrounding wall comprising lower sidewall 18′ and bottom wall 30, and with a feed through 46 in said bottom wall 30;
a second electrode shield formed as metal partition wall 12′ traverse to said central axis A and separating said etching compartment 31 from said pumping compartment 32;
at least one pumping slit 44 in or along said metal partition wall 12′ looping around said central axis A and establishing a pumping flow communication between the inner space of said etching compartment 31 where the ICP is formed and an inner space IP of said pumping compartment 32;
a pumping port 45 in said metal surrounding wall of said pumping compartment 32;
a substrate support 11′ which again is a pedestal 11′ centered about said central axis A, adapted to support a substrate exposed to said inner space IE of said etching compartment 31 and being mounted in said vacuum chamber 2 in an electrically isolated manner, said substrate support 11′ being drivingly movable F up in an etching position and down away from said etching position, both along said central axis A;
a metal tubular arrangement 47 through said feed through opening 46 extending towards said pedestal 11′, said metal tubular arrangement comprising a first part 48 mechanically coupled to said pedestal 11′ and a second part 49 mechanically coupled to said bottom wall 30 of the metal surrounding wall of said pumping compartment 32, said first 48 and second parts 49 being movable F relative to one another in direction of said central axis A, said second part 49 being electrically conductively joint 50 along an edge of said feed through opening 46 to said metal surrounding wall;
an RF feed line 51 through and along said metal tubular arrangement 47 and connected to said pedestal 11′;
a system ground connector 52 for said plasma etch device 1 at an end of said second part 49 of said metal tubular arrangement 47 outside said metal surrounding wall 18′,30 of said pumping compartment 32, or at said metal surrounding wall 18′, 30 opposite said metal partition wall 12′;
a multitude of distributed metal connectors 53 establishing electric contact from said metal surrounding wall 18′ of said pumping compartment 32, across said at least one pumping slit 44 via said metal partition wall 12′ to said first part 48 of said metal tubular member 47, at least when said pedestal is in said etching position. Whereby the first part 48 of said metal tubular member 47 forms a dark space shield 55 around the pedestal.

Said metal connectors may comprise plate shaped connectors and may be one of rigid and of resilient.

With reference to further embodiments and examples of a plasma etching device comprising a dynamic chuck, it is referred to WO 2017/207144 which is hereby integrated by reference in its entirety.

It should be mentioned that all features as shown or discussed in connection with only one of the embodiments of the present invention and not further discussed with other embodiments can be seen to be features well adapted to improve the performance of other embodiments of the present invention too, as long such a combination cannot be immediately recognized as being prima facie inexpedient for the man of art, as for instance using a movable metal tubular arrangement with a static pedestal. Therefor with the exception as mentioned all combinations of features of certain embodiments can be combined with other embodiments where such features are not mentioned explicitly and form part of the present invention.

For processes in the CLN300E equipment in general Argon was used as a process gas at low pressure of 0.1 Pa or high pressure of 0.5 Pa for etching of oxides or metal oxides. Therefor an Argon flow of about 5 sccm (low pressure) via the central gas inlet has been set. However, when state of the art etching processes using Ar gas only where performed on ITO full face (100%) coated semiconductors, particle performance was very poor as shown in FIG. 3. There it can be seen that with the first scheduled particle monitoring on wafer number 325, a number of 170 added particles having a size of greater 0.2 μm was measured, which is far beyond an internal specification of 30 added particles of that size. Only a few runs later with wafer 330, the situation even got much worse with 497 added particles on the wafer surface. Obviously heavy flaking from the shields 13′, 13″ of the third electrode 13 of the etching compartment has occurred, which is mainly due to re-deposited ITO material. The etching of the wafer sequence has been run without pasting wafers in between.

In the following process parameters where changed by tempering the shields 13, 13′ and the pedestal 11 with a fluid having a temperature slightly above 100° C. before the etching started so that a substrate surface temperature could be adjusted at 100±10° C. during the whole process with the help of an IR-measurement device used to control the heating and cooling means by the process control unit of the device, which switched the heating and cooling system from heating to cooling in the moment when excessive process heat has been induced by the RF- and MF-sources at the beginning of the etching process. Additionally, a methane portion of 10% to the Ar-flow has been used with the process gas. Thereby particle situation could be influenced in a very positive direction as shown in FIG. 4. Starting again from a carefully cleaned vacuum chamber, even after having etched 10′034 wafers, which refers to 25 nm of a full-face ITO layer etched off per wafer, in total 250 μm removed ITO, the particle count remained well within the specification of less than 30 adders >0.2 μm The etching of the wafer sequence has been run without pasting wafers in between. This improvements could be achieved by using one and the same heating and cooling device 16 to feed the internal fluid circuits 35 and 36 of the pedestal and the top wall 19. Therefor first cooling means 16′, 35 and second cooling means 17′, 36 can be supplied by the first cooling device 16, which thereby also substitutes the second cooling device 17.

However further experiments not discussed in detail here have been performed with separate heating and cooling means 16, 16′ and further heating means for the shields 13′ and 13″. Thereby substrate temperature could be lift even to a higher level to speed up the etching process and shield temperature could be held on a more constant level over a series of etching processes and loading and idle time between to minimize flaking of due to different CET between shield material and redeposited ITO layers or islands.

An additional positive effect could be seen when applying supplementary cooling means 29, 29′ to run lower shields 12 of the second electrode as a cool trap with about −30° C., therewith further minimizing the in film adders count of etched wafers.

A simplified mechanism of ITO etch and particle prevention could be therefore understood by the following basic steps:
1) Plasma dissociation of CH₄ to the radicals —CH₃° and —H°;
2) Reduction of the ITO surface to the metallic state;
3) Sputtering of In and Sn by Ar-ions;
4) Formation of volatile metalorganic products like Trimethyl-indium or Tetramethyl-tin. The latter reaction can be also induced catalytically accelerated at the hot surface of the shields exposed to the plasma to avoid mostly redeposition of ITO islands or layers.

As it can be easily seen the “ion-etching” step 3) and “reactive etching” step 4) are competing. Without ion etching however the process would be too slow. Also an etching process by radicals only will not provide a vertical etch profile under the etch mask which is in this case photoresist. On the other side reactive etching is in particular attacking less dense material, which is in particular prone to form particles. The reactive etching process by radicals also takes place on the chamber walls. To achieve low particle levels the process parameters are adjusted in a way to achieve the lowest deposition on the chamber walls.

Conditioning of the etching compartment by sputtering of pasting material like aluminium or titanium after a certain number (wafer count) of ITO etch processes, which is known as “pasting”, can also be used to decrease particle adders. This is common practice especially for etch processes on substrates comprising polymers on the surface. Such tests have been performed immediately after an etching process had been run with Ar gas. Thereby the particle count could be decreased below the specified level of 30 adders (not shown here). Pasting processes can also be applied by using in-situ pasting during the ITO etching process, when pasting material can be etched from parts of the pedestal made or coated with such material, e.g. an aluminium or titanium ring round the circumference of a wafer, and re-deposited on the shields. Alternatively pasting can be performed between a certain number of etching processes (wafer count) by etching pasting disks or wafers, made or coated from/with pasting material. With pasting processes, as an example the same parameters can be applied as with preceding etching processes with Ar only, whereby the kit life of the shields 12, 13 can be extended. At the same time the pasting parameter P{f_{PR_cov}}=(No of produced wafers)/(No of pasting wafers), can be chosen much higher, e.g. by a factor 25 to 1'000 when applying inventive processes compared to state of the art ones, which altogether gives a considerably higher productivity and less rejection rate.

As ITO etch rate is enhanced by temperature the pedestal should be hold at temperatures above RT to 100° C. For this purpose also ESCs can be used to keep the wafer temperature close to pedestal temperature which can be further improved by back gas application as described above. In cases that a thicker ITO layer must be removed and substrates with photoresist masks are used, which have a temperature limit of 120° C., intense cooling of the wafer and pedestal may be required. Further on shield temperature can be adjusted to a temperature from −40 to +150° C. to avoid thermal cycling of the shields and thereby prevent particle generation based on mismatch between material CTE with tempered shields of the 3^{rd} electrode to avoid layer formation and/or cooled shields of the 2^{nd} electrode to trap volatile particles and dust.

Further on the following features and process parameters alone or in combination seem to foster low particle plasma etch processes combined with a high etching rate:
a) Using an ICP plasma setup with electron densities >3 e⁺¹⁰ cm⁻³ or even >1 e⁺¹¹ cm⁻³, as described in U.S. Pat. No. 6,814,838. Thereby a low process pressure can be used. On the substrate pedestal a high frequency of 13.56 MHz is applied. Alternatively, also frequencies like the industrial 2 MHz or 27.01 MHz be applied. For preferred ranges for MF-source 10 and HF-source 8 see above.
b) A reducing process gas, such as hydrogen or hydrocarbon, capable to form volatile reaction products from In, Sn or Zn is introduced as a fraction in inert gas. Preferred is CH₄ in Ar, where a CH₄ fraction from:
   ≥10% to enable an effective reaction into volatile products to
   ≤50% to prevent deposits of CH₄ by plasma polymerization as good as possible.
c) A slotted metallic screen shield 13″ as described in U.S. Pat. No. 6,814,838 to avoid formation of a continuous conductive film deposition on the upper side walls 18 of the ICP dome, however with an essentially higher shield thickness of 3 mm up to 6 mm has been proved to be the preferred solution since the screen shield 13″ then can be actively cooled via thermal conduction from the upper shield 13′ and electrode 13 can be easily exchanged for maintenance. A high surface high roughness, e.g. 0.8 μm≤Ra≤12.5 μm produced by sandblasting of the shields, or an even higher roughness, e.g. 5 μm≤Ra≤50 μm produced by twin wire arc spray of (TWAS) of Aluminium, can also improve adhesion of the etched layers whereas slots tilted with reference to a radial direction can further improve the shielding effect towards the ceramic wall 18.
d) Temperature control provided to the pedestal 11 allows also processing of sensitive substrates at considerable etching rates due to tight temperature control (embedded substrates or temperature sensitive photo resists which may be used as an etch mask).
e) To reach a high pumping speed within the ICP compartment, typically a turbomole-cular pump having a pumping speed of 1200 l/s is provided to the pumping compartment. Due to optimized pumping slit(s) 44 within lower shield 12, and/or further respective slits between lower shield 12 and pedestal 11, 11′ or the tubular arrangement 47, 48 an effective pumping speed of at least 200 l/s or better >300 l/s inside the ICP compartment could be set to enable quick pumping of volatile reaction products. Pump slits where circular and had a width of 10 to 15 mm whereby plasma spill-out could be avoided and a still a good pumping conductivity could be reached. The volume of the etching compartment used was about 30 l (d=480 mm, h=160 mm).
f) The shields 12, 13 should be made of aluminium or titanium or combinations of both metals. While Al provides a better heat conductivity to distribute the tempering application (heating and cooling), titanium has the advantage of a low thermal expansion with the effect that TCO or ITO residues adhere better to the shields. Since a complete conversion of TCO/ITO into volatile reaction products is not very likely there will always be remaining areas of TCO/ITO deposition in the chamber, most likely close to the substrate. As a consequence, lower shields 12 close to the pedestal 11 should be made of Titanium, while more remote shields of the second electrode 13, 13′, 13″ should be made of Aluminium to provide a tempered surface more easily.
g) A flush step of 5 to 30 sec after each RIE step with inert gas only (Ar) helps to purge out volatile reaction products.
h) An addition of hydrogen in the range of 5 to 30% to the CH₄/Ar mixture further reduces dust formation.
i) The application of a pasting procedure to reset the chamber walls strongly depends on the fraction of polymer on the substrate, it may be necessary after 1 μm etched TCO or ITO with 80% photoresist, or after 5 μm with 50% photoresist or even 250 μm etched TCO/ITO with no photoresist. This pasting procedure comprises a sputter step from a substrate made of or coated with a gettering material, using Ar-gas only. Since in practice the etched wafer surface is not only ITO, the above mentioned pasting frequency may vary significantly from 1 pasting per 25 product wafers for a highly photoresist-covered surface up to 1 pasting per 10'000 product wafers with a high fraction of ITO on their surface.
j) Alternatively, an implementation of an in-situ-pasting similar as described in U.S. Pat. No. 9,719,177 can be used where the pedestal itself is coated or made from a pure metal (such as Ti or Al) useful as a getter. In this embodiment the pedestal may include a perimeter area of its upper surface that extends radially outward from the wafer or a protection ring surrounding the wafer, which perimeter area is unprotected by any dark space shield 55 and therefore is open to plasma sputtering during the sputtering operation. In this embodiment, the etching chamber is continuously conditioned by sputtering titanium or other getter material from the pedestal itself whenever the plasma and RF bias connected to the pedestal are active; i.e. during the sputtering operation for the wafer.

### REFERENCE NUMBERS

1 plasma etching device
2 vacuum chamber
3 substrate handling opening
4 vacuum pump system
5 vacuum pump
6 pump valve
7 pump exhaust valve
8 1^{st} RF-source
9 coil
9′, 9″ first end, second end of the coil
10 2^{nd} MF-source
11 1^{st} electrode, pedestal, chuck, substrate support (static)
11′ 1^{st} electrode, pedestal, chuck, substrate support (dynamic)
12 2^{nd} electrode (shield), also lower shield
13 3^{rd} electrode
13′ upper (electrode) shield of the 3^{rd} electrode
13″ screen (electrode) shield of the 3^{rd} electrode
14 electrostatic chuck (ESC)
16,16′,17,17′,29, 29′,35,36 heating and cooling means
16 first heating/cooling device for 1^{st} electrode, e.g. combination of heater and chiller for a liquid medium
16′ 1^{st} heating/cooling lines
17 further heating/cooling device for upper shield, 3^{rd} electrode
17′ 3^{rd} (further) heating/cooling lines
18 upper side-wall (dielectric: ceramic or quartz)
18′ lower sidewall
19 top-wall
20 1^{st} gas supply
21 1^{st} gas reservoir
22 1^{st} gas inlet valve
23 back (2^{nd}) gas supply
24 back (2^{nd}) gas reservoir
25 back (2^{nd}) gas inlet (valve)
26 vacuum gauge
27 substrate
28 substrate handling opening
28′ substrate handling cut-out
29 3^{rd} (supplementary) heating/cooling device for lower shield, 2^{nd} electrode
29′ 3^{rd} (supplementary) heating/cooling lines
30 bottom wall
31 etching compartment
32 pumping compartment
33 pedestal basis
34 central gas inlet
35 liquid circuit
36 further liquid circuit
37, 37′ temperature measurement system
38 gate, e.g. a load-lock
39 channel for back gas
40 Langmuir probe
41 DC source (pulsed or continuous)
42 LC network (Filter)
43 adapter network
44 pumping slit
45 pumping port
46 feed through opening
47 metal tubular arrangement
48 first part
49 second part
50 conductively joint
51 RF feed line
52 system ground connector
53 metal connector
54 pin(s)
55 dark space shield

What is claimed is:

1. A plasma etching device comprising
a vacuum chamber (2) for at least one plate shaped substrate with side walls (18, 18′) looping around a central axis (A), the chamber including
a substrate handling opening (28);
at least one inlet (34) for a reductive gas and an inert gas;
a pedestal (11, 11′) formed as a substrate support in a central lower area of an etching compartment (31) of the chamber (2), the pedestal (11) being mounted in the chamber (2) in an electrically isolated manner and connected to a first pole of a first voltage source (8), thereby forming a first electrode (11, 11′), the pedestal encompassing first heating and cooling means (16, 16′, 35);
a second electrode (12, 12′) electrically connected to ground and surrounding the first electrode (11, 11′);
a third electrode (13) electrically connected to ground comprising at least one upper shield (13′) and a screen-shield (13″) both being thermally and electrically connected to each other, whereby the screen-shield (13″) loops around the etching compartment (31);
whereby at least one of the upper shield (13′) and the screen shield (13″) comprises at least one further heating and/or cooling means (17, 17′, 36)
the device (1) further comprising a vacuum pump system (4) and an inductive coil (9) looping around at least an upper sidewall (18) defining the sidewall of the etching compartment (31), whereby one first end (9′) of the coil (9) is connected to a first pole of a second voltage source (10) and one second end (9″) of the coil is connected to ground.

2. The plasma etching device according to claim 1, wherein the control means comprise a control circuit to set heating power and/or cooling power in dependency of the substrate temperature measured by a temperature measurement device.

3. The plasma etching device according to claim 1, wherein a lower shield (12) which constitutes the surface of the second electrode is connected to further heating and/or cooling means (17, 17′, 36) or comprises supplementary heating and/or cooling means (29, 29′).

4. The plasma etching device according to claim 1, wherein at least one of the first heating means (16, 16′, 35), further heating means (17, 17′, 36), and supplementary heating means (29, 29′) comprise an electrical resistance heating device, a radiation heating device or at least one heating circuit comprising a heating fluid, and at least one of the first cooling means, further cooling means, and supplementary cooling means comprise at least one cooling circuit encompassing a cooling fluid.

5. The plasma etching device according to claim 1, wherein at least one of the first heating means (16, 16′), further heating means (17, 17′, 36), and supplementary heating means (29, 29′) comprise a fluid circuit the intake of which is connected to two fluid reservoirs of different temperature and a mixing unit to set the heating/cooling temperature.

6. The plasma etching device according to claim 5, wherein at least one of the heating and cooling circuit (16′, 35) and heating and/or cooling circuits (17′, 36, 29′) is mounted directly to or in at least one of the pedestal (11, 11′) and the shields (12, 13, 13′, 13″).

7. The plasma etching device according to claim 5, wherein at least one heating and/or cooling circuit (17′, 29′) is mounted within a chamber wall to heat or cool at least one of the shields (12, 13′, 13″) by an extensive contact area between respective wall (18′, 19) and respective shield (12, 13′, 13″).

8. The plasma etching device according to claim 1, wherein the at least one inlet (34) is connected to at least one reservoir of a reductive gas (21′) and to at least one reservoir of an inert gas (21).

9. The plasma etching device according to claim 8, wherein the reductive gas comprises at least one of hydrogen, and a hydrocarbon gas volatile at room temperature and the Inert gas comprises at least one of Argon (Ar), Helium (He), Neon (Ne) and Xenon (Xe).

10. The plasma etching device according to claim 1, wherein the screen shield (13″) is slotted, for instance in parallel to central axis (A) of the pedestal (11, 11′).

11. The plasma etching device according to claim 1, wherein the upper shield (13′) and the screen-shield (13″) are made as a single piece element (13).

12. The plasma etching device according to claim 1, wherein at least the upper shield (13′) or the upper shield (13′) and the screen-shield (13″) are made of 3 to 5 mm thick Aluminum.

13. The plasma etching device according to claim 1, wherein the pedestal (11, 11′) comprises an electrostatic chuck ESC (14).

14. The plasma etching device according to claim 1, wherein the pedestals (11, 11′) surface comprises an open channel (39) with a central feedthrough to a back-gas inlet (25).

15. The plasma etching device according to claim 1, wherein at least one substrate-handling opening (28) is provided in upper side wall (18) or lower sidewall (18′) with an opening central axis perpendicular to and intersecting said central axis A.

16. The plasma etching device according to claim 15, wherein the pedestal (11) is a static pedestal and at least one substrate handling cut-out (28′) is provided in screen (13″) mutually aligned with substrate handling opening (28).

17. The plasma etching device according to claim 1, wherein the pedestal is a dynamic pedestal (11′) comprising means (47, 48, 49) to lower the pedestal in downwards direction from a process position for wafer etching into a loading position and vice versa.

18. The plasma etching device according to claim 17, wherein the means comprise a metal tubular arrangement (47, 48, 49) extending through a feed through opening (46) being mechanically coupled to the pedestal (11′).

19. The plasma etching device according to claim 18, wherein at least one pumping slit 44 in or along the second electrode (12, 12′) is looping around said central axis A and establishes a pumping flow communication between the inner space IE of said etching compartment (31) to the inner space IP of the pumping compartment (32) and a multitude of distributed metal connectors (53) are arranged to establish an electric contact from the metal surrounding wall (18′) of the pumping compartment (32), across the at least one pumping slit (44) via the second electrode (12′) to a first part (48) of a metal tubular member (47), at least when the pedestal (11′) is in etching position.

20. A process for plasma-etching a semiconductor substrate in a plasma etching device (1), the plasma etching device comprising:
a vacuum chamber (2) for at least one plate shaped substrate with side walls (18, 18′) looping around a central axis (A), the chamber including
a substrate handling opening (28);
at least one inlet (34) for a reductive gas and an inert gas;
a pedestal (11, 11′) formed as a substrate support in a central lower area of an etching compartment (31) of the chamber (2), the pedestal (11) being mounted in the chamber (2) in an electrically isolated manner and connected to a first pole of a first voltage source (8), thereby forming a first electrode (11, 11′), the pedestal encompassing first heating and cooling means (16, 16′, 35);
a second electrode (12, 12′) electrically connected to ground and surrounding the first electrode (11, 11′);
a third electrode (13) electrically connected to ground comprising at least one upper shield (13′) and a screen-shield (13″) both being thermally and electrically connected to each other, whereby the screen-shield (13″) loops around the etching compartment (31);
whereby at least one of the upper shield (13′) and the screen shield (13″) comprises at least one further heating and/or cooling means (17, 17′, 36)
the device (1) further comprising a vacuum pump system (4) and an inductive coil (9) looping around at least an upper sidewall (18) defining the sidewall of the etching compartment (31), whereby one first end (9′) of the coil (9) is connected to a first pole of a second voltage source (10) and one second end (9″) of the coil is connected to ground,
whereby the process comprises the following steps:
applying a vacuum to the chamber (2);
tempering the 2^{nd} electrode shields (13, 13′, 13″) and the pedestal (11);
putting a substrate (27) on the pedestal (11);
setting a process pressure by introducing a gas mixture comprising an inert gas and at least one reductive gas;
applying a power from the first voltage source (8) to the pedestal (11) to produce an etch bias;
applying a power from the second voltage source (10) to the coil (9) to produce an inductively coupled plasma (ICP);
etching the substrate surface by reactive ion etching (ME), and
controlling the substrate temperature during ME by adjusting the heating or cooling power of the heating and cooling device (16) of the pedestal (11, 11′) in dependency of the substrate temperature measured by at least one temperature measurement device.

21. The process according to claim 20, wherein the reductive gas is at least one of a hydrocarbon being volatile at room temperature and hydrogen.

22. The process according to claim 21, wherein the hydrocarbon is methane.

23. The process according to claim 22, wherein a methane proportion from 10 to 50% is used in the gas mixture.

24. The process according to claim 20, wherein the reductive gas comprises or is a mixture of methane and hydrogen.

25. The process according to claim 21, wherein a hydrogen proportion from 5 to 30% is used in the gas mixture.

26. The process according to claim 20, wherein tempering comprises heating of at least the substrate surface to be etched to or near an etch temperature between 30° and 200° C. by at least one of heating the pedestal with heating and cooling means (16, 16′, 35) and heating a substrate surface by radiation heating.

27. The process according to claim 20, wherein controlling the substrate temperature comprises to keep the temperature constant within ±10° C. by at least controlling the temperature of the pedestal in a temperature region from −40 to 200° C. in dependency of at least one of a pedestal or shield reference temperature measured with an electric temperature measurement device (37′) and/or a substrate reference temperature measured with an optic measurement device (37) at the back-side surface of the substrate.

28. The process according to claim 27, wherein the temperature measurement device (37′) comprises one of a thermocouple, thermistor, resistance temperature detector (RTD) in a surface of the pedestal or a shield and/or an infra-red (IR) or pyrometer measurement device for the backside of the substrate.

29. The process according to claim 20, wherein tempering comprises heating of the third electrode shield(s) (13, 13′, 13″) to a temperature between 30° and 100° C.

30. The process according to claim 20, wherein tempering comprises heating or cooling of the lower shield(s) to a temperature between −40° and 100° C.

31. The process according to claim 20, wherein the first voltage-source (8) is an RF-source and is driven with a frequency from 2 MHz to 30 MHz.

32. The process according to claim 31, wherein a power of the RF-source (8) is applied to the pedestal (11) in the range from 0.3 Wcm⁻² to 1.4 Wcm⁻².

33. The process according to claim 20, wherein the second voltage source (10) is an MFsource and is driven with a frequency from 300 to 2'100 Hz.

34. The process according to claim 33, wherein a power of the MF-source (10) is applied to the chamber (2) giving an electron density from 1 e¹⁰ cm⁻³ to 5 e¹¹ cm⁻³.

35. The process according to claim 20, wherein an electrostatic chuck (ESC) is used to improve thermal contact between wafer (27) and pedestal (11).

36. The process according to claim 20, wherein an ITO-etch rate is achieved in the range of 0.6 to 1.2 nm/s.

37. A series of processes according to claim 20, wherein a pasting parameter
P{f_{PR_cov}}=(No of produced wafers)/(No of pasting wafers),
for wafer processes, where PR_cov is the surface coverage of the TCO layer with photo resist, can be chosen at least within one of the following ranges referring to different surface coverages (PR_cov) of a TCO-coated wafer:
25≤P(80%)≤50
100≤P(50%)≤200
2'000≤P(0%)≤10'000
whereby an in film adders count can be measured below 30, for particles >0.2 μm, for every single process.

38. The series of processes according to claim 37, wherein the shield temperature(s) is(are) held constant at elevated temperatures before, during and after the first process over a series of processes until the shield(s) are changed for service.

39. A process to produce a wafer or a series of wafers comprising the plasma etch process according to claim 20.

40. A process to produce a wafer or a series of wafers comprising a series of plasma etch processes according to claim 37.
